(19) United States
(12) Patent Application Publication
(10) Pub. No.: US 2022/0035243 A1
(43) Pub. Date: Feb. 3, 2022

(54) ORIGINAL PLATE MANUFACTURING METHOD, DRAWING DATA CREATION METHOD, AND PATTERN DEFECT REPAIRING METHOD

(71) Applicant: KIOXIA CORPORATION, Tokyo (JP)

(72) Inventors: Ryoji YOSHIKAWA, Yokohama Kanagawa (JP); Masato NAKA, Yokohama Kanagawa (JP)

(21) Appl. No.: 17/190,078

(22) Filed: Mar. 2, 2021

(30) Foreign Application Priority Data
Aug. 3, 2020 (JP) 2020-131828

(51) Int. Cl. G03F 1/72; G03F 1/70; G03F 1/76; G03F 1/84

(52) U.S. Cl. CPC G03F 1/72; G03F 1/84; G03F 1/76; G03F 1/70

(57) ABSTRACT

An original plate manufacturing method includes preparing first design data and second design data from a predetermined pattern to be formed on a target object. The first design data corresponds to a first design pattern, and the second design data corresponds to a second design pattern. The first and second design patterns are complementary portions of the predetermined pattern. The first design pattern is then formed on the target object based on the first design data. An inspection is performed on the target object on which the first design pattern has been formed. Third design data is generated based on a result of the inspection. The second design data is then adjusted based on the third design data to generate corrected second design data. The target object is then patterned again based on the corrected second design data.

### CROSS-REFERENCE TO RELATED APPLICATION

This application is based upon and claims the benefit of priority from Japanese Patent Application No. 2020-131828, filed Aug. 3, 2020, the entire contents of which are incorporated herein by reference.

### FIELD

Embodiments described herein relate generally to an original plate manufacturing method, a drawing data creation method, and a pattern defect repairing method.

### BACKGROUND

One of the processes involved in manufacturing a semiconductor device is a process of transferring a predetermined pattern to a substrate. Examples of a technique used in this process include a photolithography technique and an imprinting technique. With the photolithography technique, a pattern drawn on an original plate called a photomask is transferred to a photosensitive polymer material on a substrate to form an etching mask. With the imprinting technique, an original plate called a template having a pattern thereon is pressed against a resist on a substrate to form an etching mask. After patterning with these techniques, an underlying layer is etched using the etching mask, and the pattern is transferred to the substrate.

Due to high integration of semiconductor devices, patterns are becoming finer (smaller minimum features), such that it becomes more difficult not only to manufacture semiconductor devices themselves but also to manufacture the original plates used in manufacturing semiconductor devices.

### BRIEF DESCRIPTION OF THE DRAWINGS

FIGS. 1A to 1D are cross-sectional views schematically showing cross sections of a template during processes of an original plate manufacturing method according to an embodiment.

FIGS. 2A to 2D are cross-sectional views schematically showing the cross sections of the template during processes of an original plate manufacturing method according to an embodiment.

FIGS. 3A to 3D are cross-sectional views schematically showing the cross sections of the template during processes of an original plate manufacturing method according to an embodiment.

FIG. 4A is a view schematically showing a part of a first design pattern by first design data.

FIG. 4B is a top view schematically showing a surface image observed by an inspection device, such as electron microscope or an atomic force microscope.

FIG. 4C is a view showing a third design pattern generated based on a comparison result.

FIG. 5A is a view schematically showing a second design pattern.

FIG. 5B is a view schematically showing a corrected second design pattern according to an embodiment.

FIG. 6A is a view schematically showing a corrected second design pattern.

FIG. 6B is a top view schematically showing a surface image observed by a surface inspection device according to a modification example.

FIG. 7 is a flowchart describing a pattern defect repairing method according to a second embodiment.

### DETAILED DESCRIPTION

Embodiments provide an original plate manufacturing method, a drawing data generation method, and a pattern defect repairing method capable of repairing pattern defects which may be generated on an original plate when fine patterns are formed on the original plate.

In general, according to one embodiment, an original plate manufacturing method includes preparing first design data and second design data from a predetermined pattern to be formed on a target object. The first design data corresponds to a first design pattern, and the second design data corresponds to a second design pattern. The first and second design patterns are complementary portions of the predetermined pattern. The first design pattern is then formed on the target object based on the first design data. An inspection is performed on the target object on which the first design pattern has been formed. Third design data based on a result of the inspection is generated. The second design data is adjusted based on the third design data to generate corrected second design data. The target object on which the first design pattern has already been formed is then patterned based on the corrected second design data.

Hereinafter, non-limiting example embodiments of the present disclosure will be described with reference to the accompanying drawings. In the accompanying drawings, like reference numerals denote like elements or components, and descriptions of the same elements will be omitted. In addition, the drawings are not intended to represent relative dimensional ratios between members and components, or thicknesses of various layers, and thus, thickness or sizes of actual components and the like should be determined by those skilled in the art according to the following non-limiting embodiments.

### First Embodiment

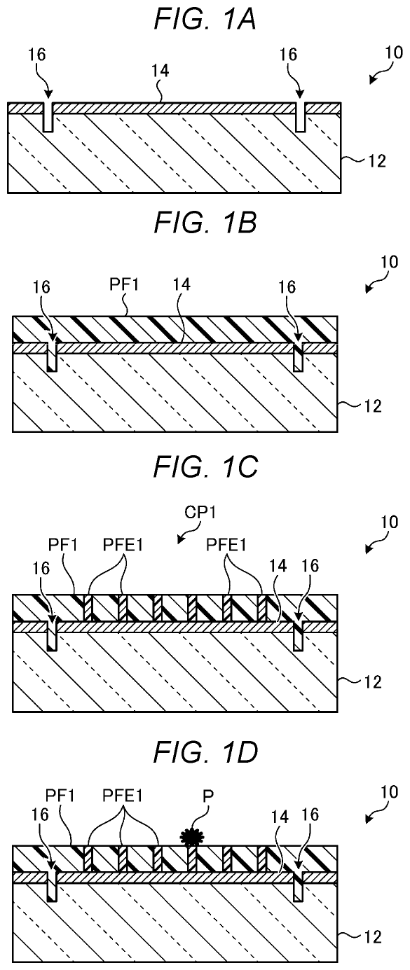

An original plate manufacturing method according to a first embodiment will be described with reference to FIGS. 1 to 3. In the following description, an imprint template (template) is taken as an example of an original plate. FIGS. 1A to 3D are cross-sectional views schematically showing cross sections of a template during various processes or stages of an original plate manufacturing method according to the first embodiment.

In the original plate manufacturing method according to the first embodiment, a starting material 10 of the template is prepared as shown in FIG. 1A. The starting material 10 includes a quartz substrate 12 and a metal film 14 formed on the quartz substrate 12. The metal film 14 serves as a hard mask for forming a pattern on the quartz substrate 12. The patterned quartz substrate 12 is used as a template in an imprint lithography process.

The starting material 10 is provided with alignment marks 16. The alignment mark 16 is implemented as an opening formed in the metal film 14 and a recess in the quartz substrate 12 formed corresponding to the opening. The alignment mark 16 is used when drawing a design pattern on the quartz substrate 12 during the manufacturing of the template. The alignment mark 16 may also be subsequently used to position the finished template relative to a substrate to be imprinted when the finished template is pressed against the resist film. In the following description, although two alignment marks 16 are particularly depicted in the drawings, it should be understood that the example includes four alignment marks 16 arranged at each of the four corners of the quartz substrate 12. Further, the starting material 10 may have, for example, a resin substrate instead of the quartz substrate 12. Like the quartz substrate 12, the resin substrate may be formed of a material that transmits ultraviolet light. Furthermore, the metal film 14 may be formed of, but is not limited to, chromium (Cr). Furthermore, an organic hard mask, such as diamond-like carbon, may be used instead of the metal film 14.

Next, as shown in FIG. 1B, a photoresist film PF1 is applied to the prepared starting material 10 so as to cover the metal film 14. In the present embodiment, the photoresist film PF1 is a positive-tone photosensitive material. Subsequently, as shown in FIG. 1C, the photoresist film PF1 is irradiated with a laser beam, such as an argon ion laser, or a charged particle beam, such as an electron beam, and a first design pattern CP1 is drawn on the photoresist film PF1 by a drawing device. As shown in FIG. 1C, the first design pattern CP1 has regions PFE1 that have been irradiated with a charged particle beam. For example, a laser beam drawing device (laser writer) or an electron beam (EB) drawing device (e-beam writer) maybe used as a drawing device. The EB drawing device can draw the first design pattern CP1 on the photoresist film PF1 by focusing an electron beam emitted from the electron gun on the photoresist film PF1 by an electron lens, and scanning the focused electron beam on the photoresist film PF1 with an electron beam deflection controlling system.

The EB drawing device includes a control unit including, for example, a central processing unit (CPU), and the control unit controls the electron gun, the electron lens, and the electron beam deflection controlling system based on design data prepared in advance. In the present embodiment, the design data is the data used for drawing the pattern that the finished template is to have (hereinafter, referred to as a template pattern). Further, the design data includes first design data corresponding to the first design pattern CP1 and second design data corresponding to a second design pattern CP2 to be described later. The first design data includes information on a shape and/or line width of the first design pattern CP1, information on an electron beam intensity (irradiation dose), and the like, and the second design data also includes information on a shape and/or line width of the second design pattern CP2, information on an electron beam intensity (irradiation dose), and the like.

The first design pattern CP1 and the second design pattern CP2 each have a pitch that is twice the pitch of the template pattern (pitch in a repetitive line-and-space pattern is equal to the sum of a line width and a space width). When these two design patterns CP1 and CP2 are combined, a finer template pattern is achieved.

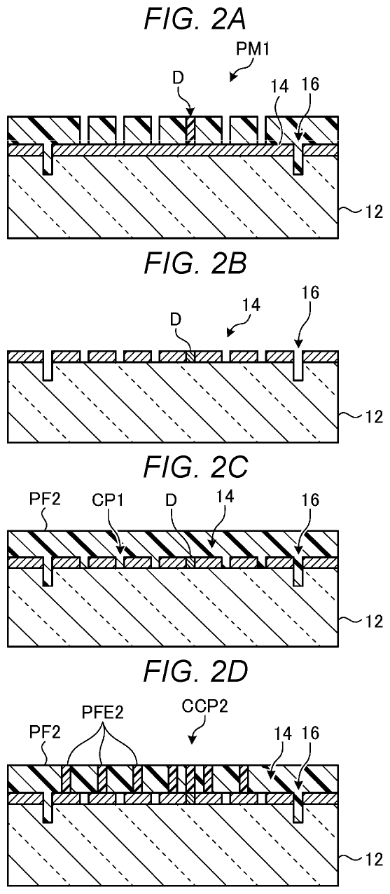

When the photoresist film PF1 on which the first design pattern CP1 is drawn is then developed, a photoresist mask having a pattern corresponding to the first design pattern CP1 is formed. Here, when a particle P is accidentally attached to the photoresist film PF1 before the development, as shown in FIG. 1D, a developing solution does not come into contact with the portion to which the particle P is attached, and therefore, a photoresist in the portion remains without being dissolved/developed, as is shown in FIG. 2A. That is, particle P causes a defect D to occur in a photoresist mask PM1. Therefore, after etching the metal film 14 using the photoresist mask PM1 and removing the photoresist film PF1 remaining on the metal film 14 by ashing, as shown in FIG. 2B, a portion that should be opened remains in the metal film 14 without being cleared. In other words, the defect D is also transferred onto the metal film 14.

Next, an inspection of the metal film 14 having the defect D shown in FIG. 2B is performed as follows. An inspection device such as an optical microscope, an electron microscope, or an atomic force microscope may be used for the inspection. Specifically, a surface of the metal film 14 is observed by one or more of these inspection devices, and image data showing the pattern as actually formed is thus acquired.

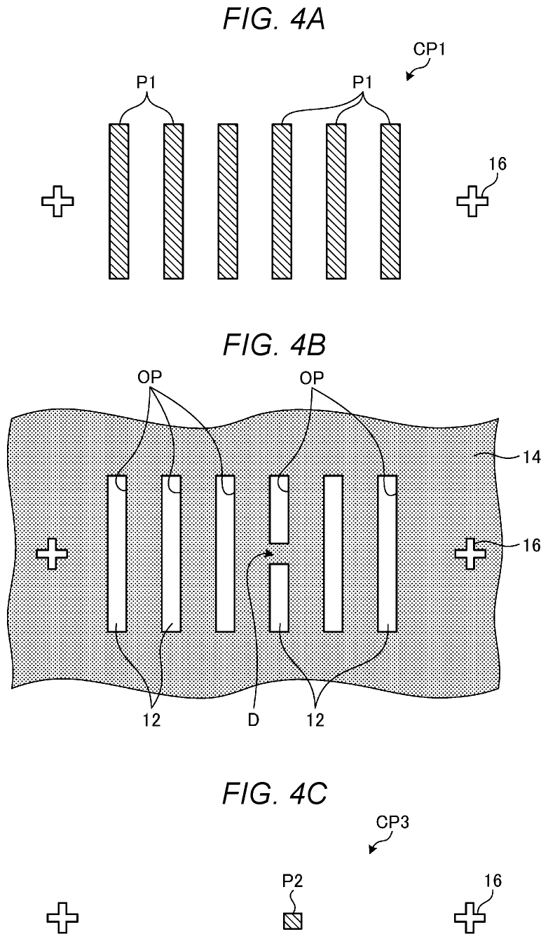

FIG. 4A is a view schematically depicting a part of the first design pattern CP1 as provided by the first design data. FIG. 4B is a top view schematically depicting a surface image of a corresponding region as actually formed including the defect D of the metal film 14, as observed by a surface inspection device. FIG. 4C is a view showing a third design pattern CP3 generated based on a comparison between the intended pattern (first design pattern CP1) and the observed pattern (FIG. 4B) provided by the surface inspection device or the like.

Referring to FIG. 4A, the first design pattern CP1 has a plurality of portions P1 to be irradiated with a charged particle beam (for example, an electron beam (EB)). Each of the portions P1 has a shape extending in a line in one direction. Further, these portions P1 are arranged at a predetermined pitch (twice the pitch of the template pattern) in a direction orthogonal to the one direction (the longitudinal direction of portions P1). On the other hand, in an observation image of the surface of the metal film 14, as shown in FIG. 4B, a portion corresponding to a portion P1 is formed as an opening OP, and the quartz substrate 12 is exposed by the opening OP. However, as described above, the defect D, caused by the particle P (FIG. 1D), is also observed. A defect such as defect D may be detected by using, for example, a pattern recognition technique based on image data of the observation image obtained by a surface inspection device, such as an optical microscope, an electron microscope, or an atomic force microscope. A shape or coordinate position of the defect may be specified based on the observation image. Furthermore, the shape and coordinate position of the defect may be obtained by comparing the observation image with the first design data. That is, since the image data depicts a structure that the first design data does not have, the extra structure (or other differences) in the image data may be understood as a defect that should not exist in the pattern. In this case, the shape and coordinate position corresponding to the defect may be recognized as a difference found when comparing the image data to the first design data. By doing so, third image data showing the shape and coordinate position of the defect is generated. FIG. 4C shows the third design pattern CP3 based on this third image data. The third design pattern CP3 has a portion P2 corresponding to the defect D, and the portion P2 is provided as a portion to be irradiated with the charged particle beam as in the portion P1.

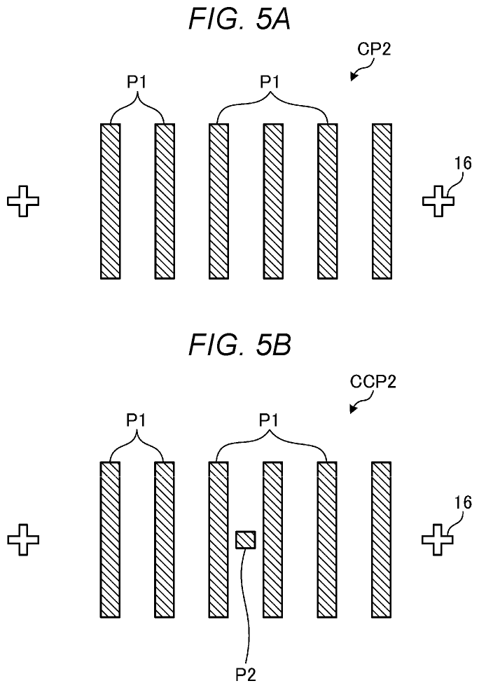

Next, the second design data is corrected based on the third design data. FIG. 5A is a view schematically showing the original second design pattern CP2 based on the second design data alone. As shown in FIG. 5A, the second design pattern CP2 has a plurality of portions P1 like the first design pattern CP1. However, the first design pattern CP1 and the second design pattern CP2 are different in that the portions P1 of the second design pattern CP2 are offset from each other by ½ pitches along the direction orthogonal to the longitudinal direction. The first and second design patterns CP1 and CP2 are complementary, non-overlapped portions of the patterned to be ultimately formed on the original plate. The third design pattern CP3 can be superimposed on the second design pattern CP2, and the second design pattern CP2 is thus adjusted to incorporate a correction of the defect D. FIG. 5B is a view schematically showing a second design pattern CCP2 corrected in this way, and a portion P2 is shown in addition to the plurality of portions P1. The corrected second design data corresponding to the corrected second design pattern CCP2 is stored in, for example, a memory unit of the drawing device.

Subsequently, as shown in FIG. 2C, a photoresist film PF2 is coated onto the metal film 14 in which the first design pattern CP1 has already been formed though including the unintended defect D. Next, the photoresist film PF2 is irradiated with a charged particle beam based on design data corresponding to the corrected second design pattern CCP2. As a result, the corrected second design pattern CCP2 is formed on the photoresist film PF2 as shown in FIG. 2D. The second design pattern CCP2 has a region PFE2 irradiated with the charged particle beam.

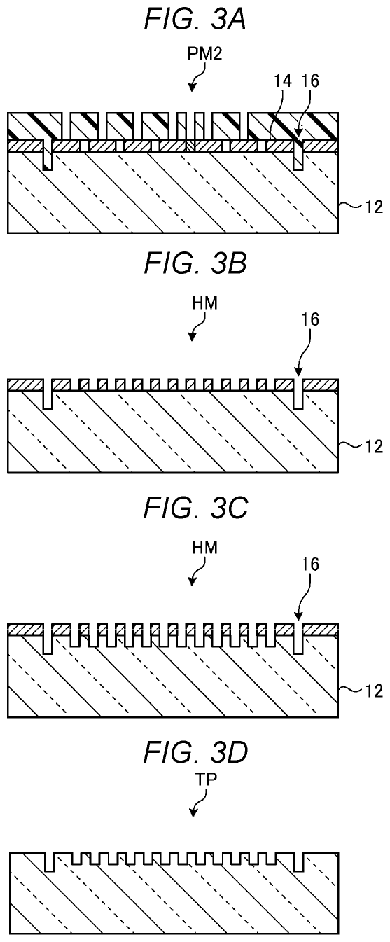

Next, the photoresist film PF2 is developed, thereby obtaining a photoresist mask PM2 as shown in FIG. 3A. As described above, the corrected second design pattern CCP2 has the portion P2 as well as the portions P1 (FIG. 5B). Accordingly, since the portion P2 is also irradiated with a charged particle beam, the portion P2 is also dissolved by the development process. Therefore, the photoresist mask PM2 has an opening in an upper side of the portion P2 as well as the portions corresponding to the portions P1.

Next, as shown in FIG. 3B, the metal film 14 is etched using the photoresist mask PM2 and then the residual photoresist mask PM2 is removed, thereby obtaining hard mask HM. The hard mask HM has the corrected second design pattern CCP2, and therefore, the hard mask HM also has a portion P2 open as well as a portion P1.

Subsequently, the quartz substrate 12 is etched using the hard mask HM (FIG. 3C), thereby substantially completing a template TP having the intended template pattern after the hard mask is removed (FIG. 3D). Here, since the hard mask HM has an opening corresponding to the portion P2, the defect D that occurred when the first design pattern CP1 was transferred to the metal film 14 is corrected.

As described above, in the original plate manufacturing method according to the present embodiment, the first design data and the second design data are first generated. The first design data and the second design data respectively correspond to the first design pattern CP1 and the second design pattern CP2, which together constitute the template pattern to be formed on the template. Next, the surface of the metal film 14 onto which the first design pattern CP1 is transferred is observed, and defects of the metal film 14 are thus detected. The third design data for repairing the detected defect is generated, and the second design pattern CP2 is adjusted based on the third design data. Based on the design data corresponding to the corrected second design pattern CCP2, the photoresist film PF2 coated onto the metal film 14 is irradiated with a charged particle beam, and the corrected second design pattern CCP2 is transferred onto the metal film 14. As a result, the hard mask HM is obtained. The hard mask HM has not only the second design pattern CP2 but also the third design pattern CP3 for repairing the detected defect in the first design pattern CP1. Therefore, the hard mask HM can have a pattern matching the intended template pattern, and the quartz substrate 12 can be etched using the hard mask HM, thereby obtaining the patterned template.

That is, according to the original plate manufacturing method of the present embodiment, the corrected second design pattern CCP2 is transferred onto the metal film 14 onto which the first design pattern CP1 has already transferred, and therefore, defects in the metal film 14 that occurred when the first design pattern CP1 was transferred can be repaired in the subsequent lithography process. Therefore, it is possible to manufacture a template having a desired template pattern with reduced defects.

Further, since the defect occurred in the metal film 14 during the transfer of the first design pattern CP1 can be repaired when the corrected second design pattern CP2 is transferred, rework immediately after the transfer of the first design pattern CP1 does not need to be performed. Thus, an extra process can be avoided, and the template can be manufactured in a short time.

If no defect is found during observation of the surface of the metal film 14 on which the first design pattern CP1 has been formed, the photoresist film PF2 is irradiated with a charged particle beam based on the second design data corresponding to the second design pattern CP2.

### Modification Example

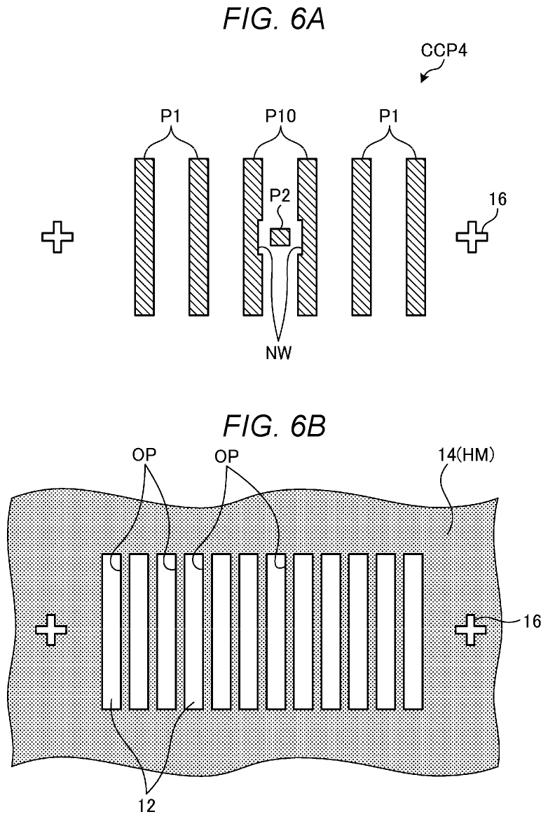

Next, a modification example of the original plate manufacturing method according to the first embodiment will be described. In this modification example, the second design pattern CP2 is adjusted (corrected) by a different method. FIG. 6A is a top view schematically showing a part of a second design pattern CCP4 that has been adjusted according to the modification example. FIG. 6B is a top view schematically showing the metal film 14 onto which the first design pattern CP1 and the corrected second design pattern CCP4 have been transferred.

As shown in FIG. 6A, the corrected second design pattern CCP4 also has a portion P2 for repairing the defect D, like the corrected second design pattern CCP2 described above. However, portions P10 extending in a line at opposite sides of the portion P2 have narrowed width portions NW facing the portion P2. This narrowed width portion NW is provided in consideration of a photolithographic phenomenon called a proximity effect.

The proximity effect is a phenomenon in which the one irradiated region is expanded in size/dimension due to scattering or reflecting of the irradiated charged particle beam within the photoresist film (PF2) from nearby (proximate) exposures. The effect is particularly remarkable when the adjacent irradiated region(s) irradiated by the charged particle beam are close to one another. When a pattern (portion P2), which is not present in the original second design pattern CP2, is added as in the corrected second design pattern CCP4, the spacing between the portion P2 and each portion P10 is narrower than the spacing between the portions P1, which is likely to produce the proximity effect. Therefore, by providing the narrowed width portion NW having a smaller pattern width in the portion P10, the distance from the portion P2 is increased, and an influence on the proximity effect is reduced or compensated. That is, the second design pattern CP2 is not only corrected based on the third design pattern CP3, but also corrected by providing the narrowed width portion NW. The metal film 14 (including the defect D) onto which the first design pattern CP1 was transferred is patterned using the corrected second design pattern CCP4 thus obtained, thereby obtaining a hard mask HM with the intended pattern. As shown in FIG. 6B, the hard mask HM is formed with an opening OP having substantially the same shape as the portions P1 of the first design pattern CP1 and the second design pattern CP2.

The appropriate width and/or length (along the longitudinal direction of the portion P10) of the narrowed width portion NW may be determined by, for example, an irradiation dose correction method disclosed in JP-A-9-289164. This reference (JP-A-9-289164) discloses a method of calculating an optimal irradiation dose of the charged particle beam based on a size or density of the pattern (without considering defect or the like), spacing, and the like, in order to efficiently reduce the influence on the proximity effect in a charged beam drawing method. Since such a calculation is generally performed on the pattern corresponding to the entire chip, the amount of calculation involved will be large. However, in the original plate manufacturing method based on the modification example, the calculation can be performed only around the defect(s) D detected by the surface inspection, and therefore, the width or length of the narrowed width portion NW can be determined in a short time. Furthermore, improvement in calculation accuracy is expected since calculations are necessary only for small regions.

When the portion P10 is exposed in the photoresist film (PF2), a focusing diameter of the charged particle beam may be reduced and shifted when the charged particle beam has reached the narrowed width portion NW. Furthermore, when the portion P10 is formed by reciprocating the charged particle beam along the longitudinal direction of the portion P10 multiple times, the charged particle beam can be stopped in a predetermined period when the charged particle beam has reached the narrowed width portion NW, and then the irradiation can resume once the narrowed width portion NW region is passed. Furthermore, the irradiation dose of the charged particle beam can be reduced, such that the narrowed width portion NW may be realized. Accordingly, since the scattering or reflection of the charged particle beam in the photoresist film (PF2) is reduced, the influence on the proximity effect is reduced. That is, the portion irradiated with a low irradiation dose can be the narrowed width portion NW. Additionally, the irradiation dose of the charged particle beam may be reduced based on the narrowed width portion NW obtained by the calculation.

### Second Embodiment

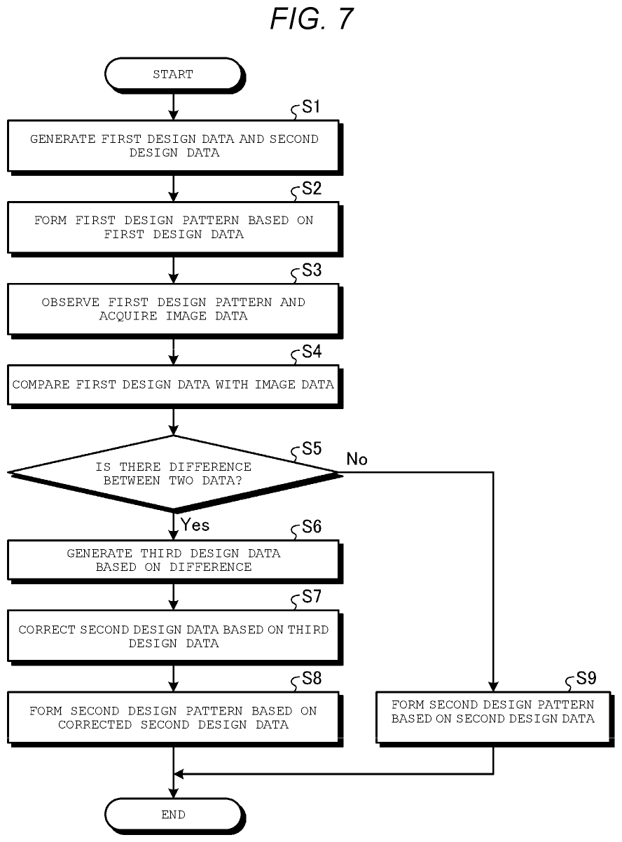

Although the original plate manufacturing method according to the first embodiment has been described so far, the present disclosure can also be implemented as a drawing data creation method and a pattern defect repairing method. FIG. 7 is a flowchart showing an example of a procedure of the pattern defect repairing method and/or drawing data creation method according to a second embodiment.

In the pattern defect repairing method according to the second embodiment, in step S1, the first design data and the second design data are generated. The first design data and the second design data each respectively correspond to the first design pattern and the second design pattern which are the formed patterns which together constitute the intended original plate pattern. The first design data includes information on a shape or line width of the first design pattern CP1, information on an intensity (irradiation dose) of the charged particle beam when using the charged particle beam, and the like, and the second design data also includes information on a shape or line width of the second design pattern CP2, information on an electron beam intensity (irradiation dose), and the like.

Next, in step S2, the first design pattern is formed, based on the first design data, on an object on which the intended pattern is to be formed. Instep S3, the formed first design pattern is observed, and image data is acquired. Next, in the second embodiment, the first design data and the image data are compared in step S4.

A difference between the first design data and the image data can then be detected (step S5). If there is no difference (step S5; NO), the second design pattern is formed, based on the second design data, on the object on which the first design pattern has already been formed (step S9), and the series of processes is completed.

On the other hand, if there is a difference between the first design data and the image data (step S5; YES), the third design data corresponding to the third design pattern is generated based on the difference (Step S6). Next, in step S7, the second design data is corrected (adjusted) based on the third design data. In step S8, the object on which the first design pattern has been formed is patterned based on the corrected second design data. The series of processes is now completed.

As a modification example of the second embodiment, the third design data maybe generated using a pattern recognition technique based on the image data acquired in step S3 instead of the comparison processing between first design data and the image data of step S4 to step S6.

### Other Examples

In the embodiments described above, the design data corresponding to the template pattern includes two individual data sets of the first design data corresponding to the first design pattern CP1 and the second design data corresponding to the second design pattern CP2. However, the sets of design data is not limited two, and the template pattern may comprise three or more individual sets of design data. In this case, the second design pattern is formed on the metal film 14 while repairing the first design pattern based on the corrected second design data (FIG. 3B), and then an inspection of the metal film 14 is performed. Based on the inspection, the third individual design data can be corrected, and the metal film 14 maybe further patterned based on corrected third individual design data.

In an above-described embodiment, the third design data showing the third design pattern corresponding to a difference between the first design pattern and an observation image is generated, but the third design data may not necessarily be data showing a design pattern. For example, the third design data can be data which is associated with information indicating the presence/absence of a coordinate position and the defect in the coordinate position, obtained by comparing between the first design data corresponding to the first design pattern and the image data of the observation image. In other words, the third design data can correct the second design data.

In embodiments described above, the hard mask HM is obtained by patterning the metal film 14 based on the corrected second design data, and the quartz substrate 12 is then etched using the hard mask HM. However, the quartz substrate 12 may be etched after the first design pattern is formed on the metal film 14 (after FIG. 2B). Even in this case, the third design pattern can be generated based on the inspection of the metal film 14 on which the first design pattern is formed. As a result, since the second design pattern can be corrected, even if the defect occurs in the metal film 14 on which the first design pattern has already been formed, these defects can be repaired. Furthermore, since the quartz substrate 12 is etched twice, a three-dimensional pattern can be formed by changing an etching amount (etch depth) in first etching and second etching.

In embodiments described above, a case of manufacturing the template as an original plate has been described as an example. However, a case of manufacturing a photomask (reticle) as an original plate can be applied to the present embodiment. In this case, as shown in FIG. 3B, if the process is stopped when the formed hard mask HM is obtained by transferring the first design pattern CP1 and the second design pattern CP2 into the metal film 14, a photomask can be manufactured. That is, since the metal film 14 blocks transmission of light, a photomask is realized by the quartz substrate 12 and the metal film 14 (hard mask HM) having a predetermined pattern formed on the quartz substrate 12. When the third design pattern CP3 is generated, the image data of the metal film 14 onto which the first design pattern CP1 has been transferred is compared with the first design data corresponding to the first design pattern CP1. However, the second design data corresponding to the second design pattern CP2 may be used. Even if there is a difference between the image data and the first design data, the difference may be ignored when the portion and the second design pattern CP2 are overlapped.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein maybe made without departing from the spirit of the disclosure. The accompanying claims and their equivalents are intended to cover such forms or modifications as would fall within the scope and spirit of the disclosure.

What is claimed is:

1. An original plate manufacturing method, comprising:
preparing first design data and second design data from a predetermined pattern to be formed on a target object, the first design data corresponding to a first design pattern and the second design data corresponding to a second design pattern, the first and second design patterns being complementary portions of the predetermined pattern;
forming the first design pattern on the target object based on the first design data;
performing an inspection on the target object on which the first design pattern has been formed;
generating third design data based on a result of the inspection;
adjusting the second design data based on the third design data to generate corrected second design data; and
patterning the target object on which the first design pattern has been formed based on the corrected second design data.

2. The original plate manufacturing method according to claim 1, wherein the forming of the first design pattern on the target object based on the first design data includes:
forming a first photoresist film on the target object;
forming a first mask by selectively irradiating the first photoresist film with a laser beam or a charged particle beam based on the first design data; and
etching the target object using the first mask as an etch mask.

3. The original plate manufacturing method according to claim 2, wherein the patterning of the target object on which the first design pattern has been formed based on the corrected second design data includes:
forming a second photoresist film on the target object on which the first design pattern has been formed;
forming a second mask by selectively irradiating the second photoresist film with a laser beam or a charged particle beam based on the corrected second design data; and
etching the target object using the second mask as an etch mask.

4. The original plate manufacturing method according to claim 1, wherein the patterning of the target object on which the first design pattern has been formed based on the corrected second design data includes:
forming a photoresist film on the target object on which the first design pattern has been formed;
forming a mask by selectively irradiating the photoresist film with a laser beam or a charged particle beam based on the corrected second design data; and
etching the target object using the mask as an etch mask.

5. The original plate manufacturing method according to claim 1, wherein the target object is a hard mask film formed on a surface of a substrate that transmits ultraviolet light.

6. The original plate manufacturing method according to claim 5, further comprising:
etching into the substrate using the hard mask film as an etch mask.

7. The original plate manufacturing method according to claim 6, further comprising:
removing the hard mask film from the substrate after the etching into the substrate.

8. The original plate manufacturing method according to claim 1, wherein forming the first design pattern on the target object based on the first design data includes etching the target object.

9. The original plate manufacturing method according to claim 1, wherein the adjusting of the second design data includes adjusting portions of the second design data to compensate for proximity effects related to the addition of the third design pattern.

10. The original plate manufacturing method according to claim 9, wherein adjusting portions of the second design data to compensate for proximity effects related to the addition of the third design pattern comprises reducing a dimension of a region in the second design data that is irradiated with a laser beam or a charged particle beam.

11. The original plate manufacturing method according to claim 9, wherein adjusting portions of the second design data to compensate for proximity effects related to the addition of the third design pattern comprises reducing an irradiation dose of a laser beam or a charged particle beam.

12. A pattern defect repairing method, comprising:
preparing first design data and second design data from a predetermined pattern to be formed on a target object, the first design data corresponding to a first design pattern and the second design data corresponding to a second design pattern, the first and second design patterns being complementary portions of the predetermined pattern;
drawing the first design pattern by irradiating a first photoresist film formed on a target object with a laser beam or a charged particle beam based on the first design data;
forming the first design pattern on the target object using the first photoresist film in which the first design pattern has been drawn;
performing an inspection on the target object on which the first design pattern has been formed;
generating third design data based on a result of the inspection;
adjusting the second design data based on the third design data to generate corrected second design data; and
irradiating a second photoresist film with the laser beam or the charged particle beam based on the corrected second design data, the second photoresist film being formed on the target object on which the first design pattern has been formed.

13. The pattern defect repairing method according to claim 12, wherein the target object is a substrate transparent to ultraviolet light.

14. The pattern defect repairing method according to claim 12, wherein the target object is a metallic film on a substrate transparent to ultraviolet light.

15. The pattern defect repairing method according to claim 12, wherein the first design pattern and the second design pattern each comprise line-space patterns having the same pitch, the second design pattern being positionally offset from the first design pattern by one-half the pitch.

16. The pattern defect repairing method according to claim 12, wherein the adjusting of the second design data includes adjusting portions of the second design data to compensate for proximity effects related to the addition of the third design pattern.

17. A drawing data creation method, comprising:
preparing first design data and second design data from a predetermined pattern, the first design data corresponding to a first design pattern and the second design data corresponding to a second design pattern, the first and second design patterns being complementary portions of the predetermined pattern;
generating third design data based on an inspection of the formed first design pattern; and
adjusting the second design data based on the third design data.

18. The drawing data creation method according to claim 17, wherein the adjusting of the second design data includes adjusting portions of the second design data to compensate for proximity effects related to the addition of the third design pattern.

19. The drawing data creation method according to claim 18, wherein adjusting portions of the second design data to compensate for proximity effects related to the addition of the third design pattern comprises reducing a dimension of a region in the second design data that is irradiated with a laser beam or a charged particle beam.

20. The drawing data creation method according to claim 18, wherein adjusting portions of the second design data to compensate for proximity effects related to the addition of the third design pattern comprises reducing an irradiation dose of a laser beam or a charged particle beam.
